(19) United States
(12) Patent Application Publication
(10) Pub. No.: US 2015/0156891 A1
(43) Pub. Date: Jun. 4, 2015

(54) PRINTED CIRCUIT BOARD AND MANUFACTURING METHOD THEREOF

(71) Applicant: Samsung Electro-Mechanics Co., Ltd., Suwon (KR)

(72) Inventors: Ki Jung SUNG, Suwon (KR); Myung Sam KANG, Hwasung (KR); Joo Hwan JUNG, Suwon (KR); Seung Yeop KOOK, Busan (KR); Young Kwan LEE, Busan (KR)

(73) Assignee: Samsung Electro-Mechanics Co., Ltd., Suwon (KR)

(21) Appl. No.: 14/209,160

(22) Filed: Mar. 13, 2014

(30) Foreign Application Priority Data
Nov. 29, 2013 (KR) 10-2013-0147343

(51) Int. Cl. H05K 3/46; H05K 1/02; H05K 1/11

(52) U.S. Cl. CPC H05K 3/4652; H05K 1/115; H05K 1/0298; H05K 2201/0137; H05K 2201/0195; H05K 2201/0191

(57) ABSTRACT

Disclosed herein are a printed circuit board and a manufacturing method thereof capable of improving poor inter-layer conduction by increasing inter-layer insulating property and rigidity. The manufacturing method of a printed circuit board includes: laminating a copper foil layer on upper and lower surfaces of an insulating layer; coating an insulating material on a surface of the copper foil layer; forming a circuit layer by etching the copper foil layer; laminating an insulator on the copper foil layer so as to enclose the insulating material and the circuit layer; forming a via in the insulator so as to be communicated with the circuit layer; and forming a circuit pattern on the insulator.

### CROSS REFERENCE(S) TO RELATED APPLICATIONS

This application claims the foreign priority benefit under 35 U.S.C. Section 119 of Korean Patent Application Serial No. 10-2013-0147343, entitled “Printed Circuit Board and Manufacturing Method thereof” filed on Nov. 29, 2013, which is hereby incorporated by reference in its entirety into this application.

### BACKGROUND OF THE INVENTION

1. Technical Field

The present invention relates to a printed circuit board and a manufacturing method thereof, and more particularly, to a printed circuit board capable of improving poor inter-layer conduction by increasing insulating property and rigidity thereof by a gravure printing method, and a manufacturing method thereof.

2. Description of the Related Art

Recently, in accordance with slimness and lightness of electronic products, as a board becomes gradually thin and fine, a semiconductor substrate and a board for a main board are also required to have high performance.

The above-mentioned slimness of the board decreases an insulating distance, thereby continuously causing issues about signal loss or noise.

The board of the electronic product which is currently released is subjected to a surface treatment process by copper foil, a coating process of a copper foil surface with a photosensitivity material, and an exposure process.

Next, an uncured photosensitivity material is removed by performing a development process and a circuit is then formed by an etching process.

Once the formation of the circuit is completed, the photosensitivity material is removed by performing a delamination process.

An insulation material is laminated on the circuit from which the photosensitivity material is removed and a hole is machined in order to electrically communicate with the circuit.

After the hole is machined, chemical copper/sputtering seed processes are performed and the circuit is formed on the insulation material after a plating process.

However, the board according to the related art has a relatively complicated manufacturing process and increases costs according to the manufacturing process as the delamination process is performed after a DFR process followed by the exposure, development, and etching processes are performed in the manufacturing process.

In addition, there is a problem in that an upper side circuit pattern and a lower side circuit pattern are electrically conducted through a thickness of the slim board, thereby causing a signal error, in addition to the problem of the manufacturing process.

### RELATED ART DOCUMENT

### Patent Document

(Patent Document 1) Korean Patent Laid-Open Publication No. 2011-0035176

### SUMMARY OF THE INVENTION

An object of the present invention is to provide a printed circuit board capable of reducing a manufacturing time and costs by simplifying a manufacturing process of manufacturing the printed circuit board and a manufacturing method thereof.

Another object of the present invention is to improve insulation performance by blocking electrical conduction between an upper side circuit pattern and a lower side circuit pattern while maintaining slimness of the board.

According to an exemplary embodiment of the present invention, there is provided a manufacturing method of a printed circuit board, the method including: laminating a copper foil layer on upper and lower surfaces of an insulating layer; coating an insulating material on a surface of the copper foil layer; forming a circuit layer by etching the copper foil layer; laminating an insulator on the copper foil layer so as to enclose the insulating material and the circuit layer; forming a via in the insulator so as to be communicated with the circuit layer; and forming a circuit pattern on the insulator.

The insulating material may be made of a mixture of an epoxy and a curing agent and may be coated on a position at which the circuit layer is formed by a gravure printing method.

The method may further include forming a seed layer on the insulator before the forming of the circuit pattern and forming a surface roughness on the surface of the copper foil layer before the coating of the insulating material.

The insulating material may be made of a material having relatively larger insulating property and rigidity than the insulator and the insulator may be made of an epoxy resin, a curing agent, or filler (silica). The insulating material may be configured in a thin type having a thickness of 2 to 5 μm.

According to an exemplary embodiment of the present invention, there is provided a printed circuit board, including: an insulating layer; a circuit layer formed on top and bottom surfaces of the insulating layer; an insulating material coated on a surface of the circuit layer; an insulator laminated on the insulating layer so as to enclose the circuit layer and the insulating material; and a circuit pattern formed on an upper surface of the insulator.

The insulating material may include a mixture of an epoxy and a curing agent and may be formed on the circuit layer by a gravure printing method.

The insulator may be provided with a via so as to implement inter-layer conduction with the circuit layer and the insulating material may be configured so as to have a thickness of 2 to 5 μm.

### BRIEF DESCRIPTION OF THE DRAWINGS

FIGS. 1A to 1G are illustration views showing processes of manufacturing a printed circuit board according to an exemplary embodiment of the present invention; and

FIG. 2 is an illustration view showing a printed circuit board according to an exemplary embodiment of the present invention.

### DESCRIPTION OF THE PREFERRED EMBODIMENTS

Hereinafter, an exemplary embodiment of the present invention will be described in detail with reference to the accompanying drawings.

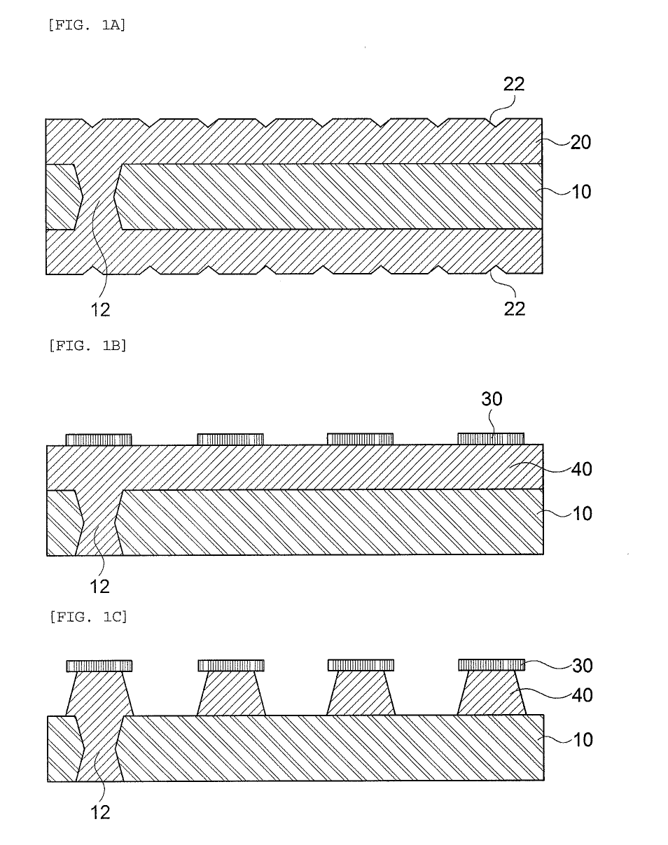

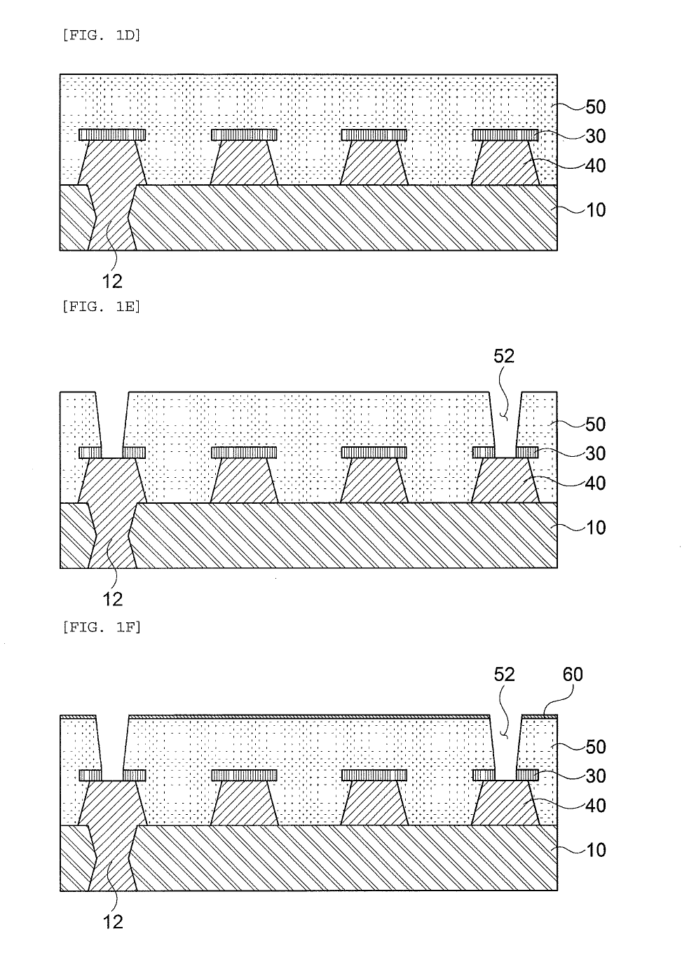

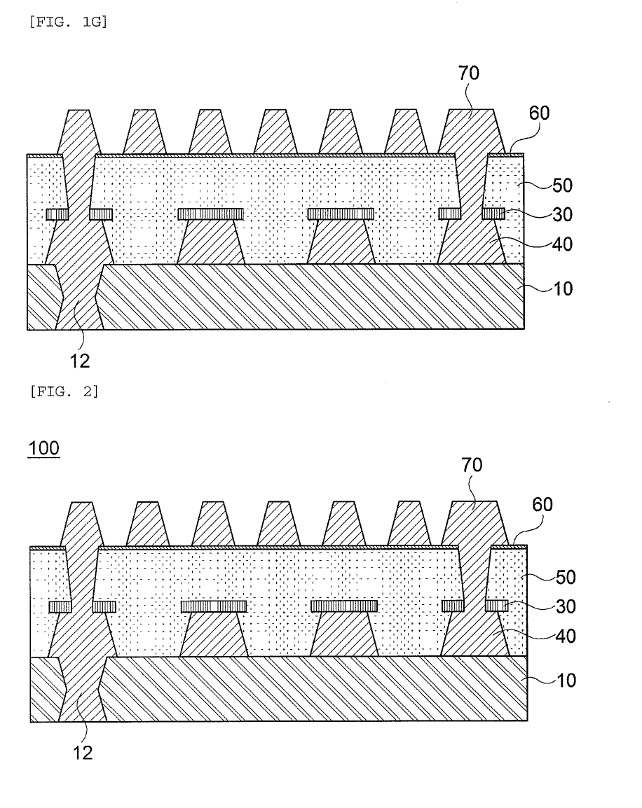

FIGS. 1A to 1G are illustration views showing processes of manufacturing a printed circuit board according to an exemplary embodiment of the present invention and FIG. 2 is an illustration view showing a printed circuit board according to an exemplary embodiment of the present invention.

As shown in FIGS. 1A to 1G, the printed circuit board and the manufacturing method thereof according to the exemplary embodiment of the present invention are to block poor inter-layer conduction due to thinness of the board by interposing an insulating material 30 between an insulating layer 10 and an insulator 50.

In order to manufacture a printed circuit board 100 according to the exemplary embodiment of the present invention, a copper foil layer 20 is firstly laminated on upper and lower surfaces of the insulating layer 10.

The insulating layer 10 may be made of a PPG material and may be used as forms of a core which is a base substance and the insulator 50 laminated on the core.

The copper foil layer 20 is each laminated on a top surface and a bottom surface of the insulating layer 10.

When the copper foil layer 20 is laminated on the upper surface and the lower surface of the insulating layer 10, a process for forming surface roughness 22 is performed on a surface of the copper foil layer 20.

The surface roughness 22 is formed so that an insulating paste, a metal paste, or the like is easily coated on the surface of the copper foil layer 20.

That is, the surface roughness 22, which is formed on the copper foil layer 20 to perform a gravure print, may be formed in advance at a position at which a circuit layer 40 is formed before a formation of the circuit layer 40, and may be formed so as to have a large or small size according to a thickness of the insulating layer 10 to be formed.

In this case, although not shown in the drawings, the gravure print is a process of printing the insulating material 30 such as the insulating paste or the metal paste on the surface of the copper foil layer 20 while a roller closely adhered to the surface of the copper foil layer 20 passes over the surface of the copper foil layer 20.

The insulating material 30 may be made of a mixture of an epoxy having excellent insulation performance and a curing agent, and for example, a biphenyl type epoxy, a phenol curing agent, and the like may be used. The insulating material 30 may be configured in a thin type having a thickness of 2 to 5 μm.

As described above, in the case in which the gravure print is performed on the surface of the copper foil layer 20, since processes such as an exposure process, a development process, and a delamination process need not to be performed after a dry film is laminated, a manufacturing process of the printed circuit board 100 may be reduced.

In the case in which the insulating material 30 is printed (coated) on the surface of the copper foil layer 20 by the gravure print, an etchant is sprayed on the surface of the copper foil layer 20, thereby forming the circuit layer 40.

The circuit layer 40 may be configured to have a trapezoidal shape in which a lower portion thereof has a width wider than that of an upper portion, and may have the insulating material 30 printed on an upper surface thereof.

Therefore, when viewing the circuit layer 40 from the top, the insulating material 30 is viewed at a central portion as a small quadrangle and the circuit layer 40 is viewed as a structure of a large quadrangle including the insulating material 30 therein.

After the circuit layer 40 is configured as described above, the insulator 50 is laminated. The insulator 50 may be made of a mixture of an epoxy resin, a curing agent, and filler (silica). The filler serves to decrease a coefficient of thermal expansion (CTE) by increasing rigidity of the insulator 50.

In this case, the insulator 50 may be provided with a via hole 52 for implementing electrical inter-layer conduction with the circuit layer 40.

The via hole 52 is machined by a laser or a drill and is formed so as to be communicated with the circuit layer 40 by penetrating through the insulating material 30.

After the via hole 52 is formed, a seed layer 60 is formed in the via hole 52 and on an upper surface of the insulator 50 by an electroless process such as a chemical copper or sputtering process.

The seed layer 60 may be formed to configure a circuit pattern 70 on the upper surface of the insulator 50.

After the seed layer 60 is formed, the copper layer 20 is laminated and the copper layer 20 is etched, thereby forming the circuit pattern 70.

Here, in the case in which the insulator 50 is again laminated on the circuit pattern 70, the insulating material 30 is coated on the circuit pattern 70 to thereby repeatedly perform the above mentioned processes.

As such, once the manufacturing method of the printed circuit board 100 according to the exemplary embodiment of the present invention is performed, a structure as shown in FIG. 2 is formed.

Referring to FIG. 2, the copper layer 20 is closely adhered to a top surface and a bottom surface of the insulating layer 10 made of a PPG, thereby forming a base substrate. A material for reinforcing rigidity of the insulator 50 such as glass fabric, glass cloth, or the like may be embedded in the insulating layer 10.

In addition, the copper layer 20 may be provided with the surface roughness 22 for improving adhesion and coating a uniform paste. The surface roughness 22 may be formed by an oxidation treatment.

Here, before the surface roughness 22 is formed, a via hole 52 may be formed in the insulating layer 10 by a laser or a drill, and a via 12 may be formed by a plating process.

The insulating material 30 is coated on the copper foil layer 20 by a gravure print. The insulating material 30 may include a mixture of an epoxy and a curing agent, and may be coated in a paste form and then cured. The insulating material 30 may have a thickness of 2 to 5 μm.

Once the gravure printing process is performed as described above, a structure in which the insulating material 30 is laminated on the upper surface of the circuit layer 40 formed by etching the copper foil layer 20 is formed. That is, when viewing the insulating material 30 from a side cross-section, a structure in which the insulating material 30 is laminated to exceed the upper surface of the circuit layer 40 approximately formed in a trapezoidal shape or have a size similar to the upper surface of the circuit layer 40 is viewed.

In addition, the insulator 50 is laminated on the upper surface of the copper foil layer 20 so as to enclose both the circuit layer 40 and the insulating material 30. The via hole 52 is formed at the respective locations electrically conducting with the circuit layer 40 by the laser or the drill.

The insulator 50 may be made of a mixture of an epoxy resin, a curing agent, and filler.

A seed layer 60 is formed on a surface of the insulator 50 as well as an inner portion of the via hole 52. In addition, a circuit pattern 70 is formed on an upper surface of the seed layer 60 by etching the copper foil layer 20.

The printed circuit board 100 according to the exemplary embodiment of the present invention configured as described above may effectively block poor inter-layer conduction generated at a position having a near inter-layer distance between the circuit layer 40 and the circuit pattern 70 by disposing the insulating material 30 made of a material having relatively larger insulating property and rigidity than the insulator 50 on the circuit layer 40.

That is, the poor inter-layer conduction which may be generated between the circuit pattern 70 and the circuit layer 40 due to the near inter-layer distance is blocked by the insulating material 30, thereby making it possible to prevent the poor inter-layer conduction.

In addition, in the case in which the insulating material 30 is formed on the upper surface of the circuit layer 40, the thickness of the insulator 50 of the printed circuit board 100 which is currently manufactured is 20 μm, but the thickness of the insulator 50 may be minimized, thereby making it possible to expect a decrease in costs.

Also, a larger number of insulating layer 10 and copper foil layer 20 than the number of inter-layer insulating layer 10 and copper foil layer 20 of a build-up board which is currently manufactured may be laminated.

The printed circuit board and the manufacturing method thereof according to the exemplary embodiment of the present invention may reduce the manufacturing time and costs by simplifying the manufacturing process of the printed circuit board and significantly increase insulation performance by blocking electrical conduction between the upper side circuit pattern and the lower side circuit pattern while maintaining slimness of the board, thereby making it possible to increase productivity.

Although the printed circuit board and the manufacturing method thereof according to the exemplary embodiment of the present invention have been described, the present invention is not limited thereto, but those skilled in the art will appreciate that various applications and modifications are possible.

What is claimed is:

1. A manufacturing method of a printed circuit board, the method comprising:
laminating a copper foil layer on upper and lower surfaces of an insulating layer;
coating an insulating material on a surface of the copper foil layer;
forming a circuit layer by etching the copper foil layer;
laminating an insulator on the copper foil layer so as to enclose the insulating material and the circuit layer;
forming a via in the insulator so as to be communicated with the circuit layer; and
forming a circuit pattern on the insulator.

2. The method according to claim 1, wherein the insulating material is made of a mixture of an epoxy and a curing agent.

3. The method according to claim 2, wherein the insulating material is coated on a position at which the circuit layer is formed by a gravure printing method.

4. The method according to claim 1, further comprising forming a seed layer before the forming of the circuit pattern.

5. The method according to claim 1, further comprising forming a surface roughness on the surface of the copper foil layer before the coating of the insulating material.

6. The method according to claim 1, wherein the insulating material is a material having relatively larger insulating property and rigidity than the insulator.

7. The method according to claim 1, wherein the insulator is made of an epoxy resin, a curing agent, or filler (silica).

8. The method according to claim 1, wherein the insulating material is configured so as to have a thickness of 2 to 5 μm.

9. A printed circuit board, comprising:
an insulating layer;
a circuit layer formed on top and bottom surfaces of the insulating layer;
an insulating material coated on a surface of the circuit layer;
an insulator laminated on the insulating layer so as to enclose the circuit layer and the insulating material; and
a circuit pattern formed on an upper surface of the insulator.

10. The printed circuit board according to claim 9, wherein the insulating material includes a mixture of an epoxy and a curing agent and is formed on the circuit layer by a gravure printing method.

11. The printed circuit board according to claim 9, wherein the insulator is provided with a via so as to implement inter-layer conduction with the circuit layer.

12. The printed circuit board according to claim 9, wherein the insulating material is configured so as to have a thickness of 2 to 5 μm.
